(19) United States
(12) Patent Application Publication
(10) Pub. No.: US 2026/0196805 A1
(43) Pub. Date: Jul. 9, 2026

(54) LASER DEVICE AND VR MODULE USING METASURFACE

(71) Applicant: LG INNOTEK CO., LTD., Seoul (KR)

(72) Inventors: Joong Hoon LEE, Seoul (KR); Gwui Youn PARK, Seoul (KR); Hyeon Yong LEE, Seoul (KR)

(21) Appl. No.: 19/129,885

(22) PCT Filed: Nov. 20, 2023
(86) PCT No.: PCT/KR2023/018604

§ 371 Date: May 14, 2025

(30) Foreign Application Priority Data
Nov. 21, 2022 (KR) 10-2022-0156428
Dec. 1, 2022 (KR) 10-2022-0165631

(51) Int. Cl. H01S 5/183; G02B 27/01; G02B 27/28; H01S 5/02

(52) U.S. Cl. CPC H01S 5/18302; G02B 27/0172; G02B 27/28; H01S 5/0207

(57) ABSTRACT

An embodiment provides a light-emitting device comprising: a substrate; a first electrode and a second electrode which are disposed on the substrate spaced apart from each other; a light-emitting unit arranged on the first electrode and the second electrode, electrically connected to the first electrode and the second electrode, and including a first conductivity-type semiconductor layer, a light-emitting layer, and a second conductivity-type semiconductor layer; and a semiconductor substrate arranged on the light-emitting unit, wherein the semiconductor substrate comprises a first surface including a first region on which a metasurface is formed, and a second surface facing the first surface and being in contact with the light-emitting unit, the metasurface protrudes from the second surface in a first direction toward the first surface, and a second region of the first surface, excluding the first region on which the metasurface is formed, is flat.

### TECHNICAL FIELD

The present invention relates to a laser device and a virtual reality (VR) module, and more particularly, to a laser device having an integrated metasurface and a VR module using the metasurface.

### BACKGROUND ART

A vertical-cavity surface-emitting laser (VCSEL) mainly used in conventional 3D modules is used as an infrared light source for driving a module. The wire-bonding process and the precision of the combination and alignment of the VCSEL and various optical elements are important factors for manufacturing the VCSEL for conventional 3D module implementation. However, tolerances of these factors cause performance degradation of the module and become a limitation in miniaturization/integration of the module.

Metamaterials refer to new materials that have properties that do not exist in nature due to artificially controlling existing materials. A metasurface is a two-dimensional planar structure that is newly made using a two-dimensional thin film with a pattern smaller than a wavelength of light. Like the metamaterials, the metasurface is being studied for application to various devices because the metasurface exhibits various optical properties that may not be found in two-dimensional materials that exist in nature.

When implementing an optical system with a single film with multiple functions by applying the metasurface to the VCSEL, it is possible to improve performance by reducing the total thickness of the existing module.

An on-chip VCSEL with a flip-chip structure in which a GaAs substrate used for an IR VCSEL substrate is processed to have an integrated metasurface may be proposed. When the metasurface is used, an optical module may be implemented at a wafer-level using a micro electro mechanical system (MEMS) process without complex alignment of the existing VCSEL and optical elements.

In addition, the combination of various optical systems such as collimating lenses, diffraction optical systems, and phase plates has been an essential component for securing the characteristics of the optical module in terms of the configuration of the optical module using the conventional laser diode. The combination of these various elements causes problems such as increased module volume, reduced efficiency due to single product/manufacturing tolerance, and decreased transmittance of each element.

There is a need to propose an optical system that implements multiple functions with a single layer by applying multiple metasurfaces to the optical system. As a result, a total thickness of existing elements may be reduced from several mm to 1 μm or less, thereby improving performance. This may be applied anywhere, such as mobile cameras, vehicles, and IoT ToF modules.

In the case of the VR module, a space of a certain level or more is required as an optical system in which a plurality of optical modules are combined using a catadioptric optical system. Therefore, when the optical module of the VR module is implemented to have the metasurface to reduce the size of the optical system, it is possible to improve the performance and efficiency of the module.

### DETAILED DESCRIPTION OF INVENTION

### Technical Problem

The present invention is directed to providing a vertical type or flip chip type laser device.

In addition, the prevent invention is directed to providing a laser device in which substrate is processed to have a metasurface.

In addition, the present invention is directed to providing a laser device at a wafer-level without complex alignment.

In addition, the present invention is directed to providing a laser device having increased efficiency by making a module compact and lightweight.

In addition, the present invention is directed to providing a virtual reality (VR) module using a plurality of metasurfaces.

In addition, the present invention is directed to providing a VR module having a reduced size and thickness.

In addition, the present invention is directed to providing a VR module having improved transmittance.

In addition, the present invention is directed to providing a VR module capable of minimizing a tolerance of arrangement during assembly.

The problem to be solved in the embodiment is not limited thereto, and the purpose or effect that may be grasped from the means or embodiment of the problem to be described below is included.

### Technical Solution

One aspect of the present invention provides a light-emitting device, including: a substrate; a first electrode and a second electrode disposed to be spaced apart from each other on the substrate; light-emitting units disposed on the first electrode and the second electrode, electrically connected to the first electrode and the second electrode, and each including a first conductivity-type semiconductor layer, a light-emitting layer, and a second conductivity-type semiconductor layer; and a semiconductor substrate disposed on the light-emitting unit.

The semiconductor substrate may include: a first surface including a first region in which a metasurface is formed; and a second surface opposite to the first surface and being in contact with the light-emitting unit, and the metasurface may protrude in a first direction from the second surface toward the first surface, and a second region of the first surface, which does not include the first region in which the metasurface is formed, may be flat.

The light-emitting unit may include a first opening that controls an area of an optical signal emitted in the first direction, and an area of the first region in which the metasurface is formed may be larger than that of the first opening.

The metasurface may include a plurality of unit structures.

A phase of the optical signal may be delayed by the plurality of unit structures.

The plurality of unit structures may include a plurality of cylinders or a plurality of quadrangular pillars protruding from the first surface in the first direction.

A design method of the unit structure may be an isotropic, anisotropic, birefringent, polarization-dependent, or polarization-independent design.

The light-emitting device may be a vertical-cavity surface-emitting laser having a flip chip structure.

The semiconductor substrate may include at least one of gallium arsenide (GaAs) and gallium nitride (GaN).

The metasurface may be formed by micro electro mechanical systems (MEMS).

The metasurface may perform at least one of focusing, diverging, and diffracting of an optical signal emitted from the light-emitting unit.

Another aspect of the present invention provides a virtual reality (VR) module, including: a display unit that radiates an optical signal; an optical system including a first optical unit, a second optical unit, a third optical unit, a fourth optical unit, a fifth optical unit, and a sixth optical unit sequentially disposed on a path of the optical signal; and a substrate disposed between the fourth optical unit and the fifth optical unit, in which the display unit and the first to sixth optical units may be disposed to be spaced a predetermined interval from each other, the fourth optical unit may focus the optical signal, the fifth optical unit may delay a phase of the optical signal, and at least one of the fourth optical unit and the fifth optical unit may be a metasurface disposed on one surface of the substrate.

The first optical unit may be a linear polarizer that transmits a P wave of the optical signal, the second optical unit may be a wave plate that delays the phase of the optical signal by ¼ wavelength, the third optical unit may be a partially reflective mirror that transmits 50% of the optical signal, the fifth optical unit may delay the phase of the optical signal by half a wavelength, and the sixth optical unit may be a linear polarizer that transmits an S wave of the optical signal. The substrate may be a gallium arsenide (GaAs) substrate.

The fourth optical unit may be a metasurface that is disposed on a surface of the substrate facing the third optical unit, and the fifth optical unit may be a metasurface that is disposed on the surface of the substrate facing the sixth optical unit.

The second optical unit may include a metasurface that delays the phase of the optical signal by ¼ wavelength.

The fifth optical unit may reflect first circularly polarized light of the optical signal and allow second circularly polarized light whose phase is delayed by half a wavelength relative to the phase of the first circularly polarized light to pass therethrough.

The optical signal may sequentially pass through the display unit, the first optical unit, the second optical unit, the third optical unit, the fourth optical unit, and the substrate, then be reflected by the fifth optical unit and sequentially pass through the substrate and the fourth optical unit, and then be reflected by the third optical unit and sequentially pass through the fourth optical unit, the substrate, the fifth optical unit, and the sixth optical unit.

The unit structure of the metasurface may have a cylinder shape or a quadrangular pillar shape.

Still another aspect of the present invention provides a VR module, including: a display unit that radiates an optical signal; and an optical system including a first optical unit, a second optical unit, a third optical unit, a fourth optical unit, a fifth optical unit, and a sixth optical unit sequentially disposed on a path of the optical signal, in which the display unit and the first to sixth optical units may be disposed to be spaced a predetermined interval from each other, the fourth optical unit may include: a first metasurface focusing the optical signal; and a second metasurface opposite to the first metasurface and delaying the phase of the optical signal by ¼ wavelength, and the fourth optical unit may allow the optical signal radiated from the display to pass therethrough at least three times.

The first optical unit may be a linear polarizer that transmits a P wave of the optical signal, the second optical unit may be a wave plate that delays the phase of the optical signal by ¼ wavelength, the third optical unit may be a partially reflective mirror that transmits 50% of the optical signal, the fifth optical unit may be a linear polarizer that reflects the P wave of the optical signal and transmits an S wave, and the sixth optical unit may be a linear polarizer that transmits the S wave of the optical signal.

The fourth optical unit may include gallium arsenide (GaAs).

The second optical unit may include a metasurface that delays the phase of the optical signal by ¼ wavelength.

The optical signal may sequentially pass through the display unit, the first optical unit, the second optical unit, the third optical unit, and the fourth optical unit, then be reflected by the fifth optical unit and pass through the fourth optical unit, and then be reflected by the third optical unit and sequentially pass through the fourth optical unit, the fifth optical unit, and the sixth optical unit.

The unit structure of the metasurface may have a cylinder shape or a quadrangular pillar shape, the phase of the optical signal after passing through the metasurface varies depending on a diameter of the unit structure, the metasurface may be made of a polymer, an insulator, or a metal material, and the metasurface may have an isotropic, anisotropic, birefringent, polarization-dependent, or polarization-independent structure.

The VR module may include: a frame that fixes the display unit and the optical system on the outside; and a band that fixes the VR module to an observer.

### Advantageous Effects

According to an embodiment, it is possible to provide a laser device whose substrate is processed with a metasurface.

In addition, it is possible to provide a laser device at a wafer-level without complex alignment.

In addition, it is possible to provide a laser device with increased efficiency by making a module compact and lightweight.

According to an embodiment, it is possible to implement a VR module using a plurality of metasurfaces.

In addition, it is possible to provide a VR module having a reduced size and thickness.

In addition, it is possible to provide a VR module having improved transmittance.

In addition, it is possible to provide a VR module capable of minimizing a tolerance of arrangement during assembly.

Various and beneficial advantages and effects of the present inventive concept are not limited to the above description and may be more easily understood in the course of describing the specific embodiments of the present inventive concept.

### DESCRIPTION OF DRAWINGS

FIG. 1 is a cross-sectional view of a conventional light-emitting device.

FIG. 2 is a cross-sectional view of a light-emitting device according to an embodiment.

FIG. 3 is a phase diagram of a metasurface of a light-emitting device according to an embodiment.

FIGS. 4a to 4l are cross-sectional views of the light-emitting device according to a process of the light-emitting device according to an embodiment.

FIG. 5 is a configuration diagram of the light-emitting device according to an embodiment.

FIG. 6 is a conceptual diagram of a conventional optical module.

FIG. 7 is a conceptual diagram of the optical module according to an embodiment.

FIG. 8 is a phase diagram in which an optical system according to an embodiment is implemented with a metasurface.

FIG. 9 is an image illustrating a unit structure of the metasurface according to an embodiment.

FIG. 10 is a configuration diagram of a VR module according to an embodiment.

FIG. 11 is a conceptual diagram of the VR module according to an embodiment.

FIG. 12 is a conceptual diagram of a VR module according to another embodiment.

### MODES OF THE INVENTION

Hereinafter, exemplary embodiments of the present invention will be described in detail with reference to the accompanying drawings.

However, the technical idea of the present invention is not limited to some of the embodiments described, but can be implemented in various different forms, and one or more of the components among the embodiments can be selectively combined or substituted for use within the scope of the technical idea of the present invention.

In addition, the terms (including technical and scientific terms) used in the embodiment of the present invention can be interpreted as having a meaning that can be generally understood by a person of ordinary skill in the technical field to which the present invention belongs unless explicitly and specifically defined and described, and the terms that are commonly used, such as terms defined in a dictionary, can be interpreted in consideration of the contextual meaning of the related technology.

In addition, terms used in the embodiment of the present invention are for explaining exemplary embodiments rather than limiting the present invention.

In this specification, singular may also include plural unless specifically stated in a phrase, and when it is described as “at least one (or more) of A and (or) B and C,” it may include one or more of all combinations that may be combined with A, B, and C.

In addition, the terms “first,” “second,” “A,” “B,” “(a),” “(b),” and the like will be used to describe components of the embodiment of the present invention.

These terms are used only in order to distinguish any component from other components, and features, sequences, or the like of corresponding components are not limited by these terms.

In addition, when it is described that a component is “connected,” “coupled,” or “connected” to another component, it may include not only cases where the component is directly connected, coupled, or connected to another component, but also cases where the component is “connected,” “coupled,” or “connected” another component with still another component therebetween.

Also, when described as being formed or disposed at “upper (above) or lower (below)” each component, the upper (above) or lower (below) includes not only the case where the two components are in direct contact with each other, but also the case where one or more other components are formed or disposed between the two components. Furthermore, when expressed as “upper (above) or lower (below),” it may include the meaning of both upward and downward directions relative to a single component.

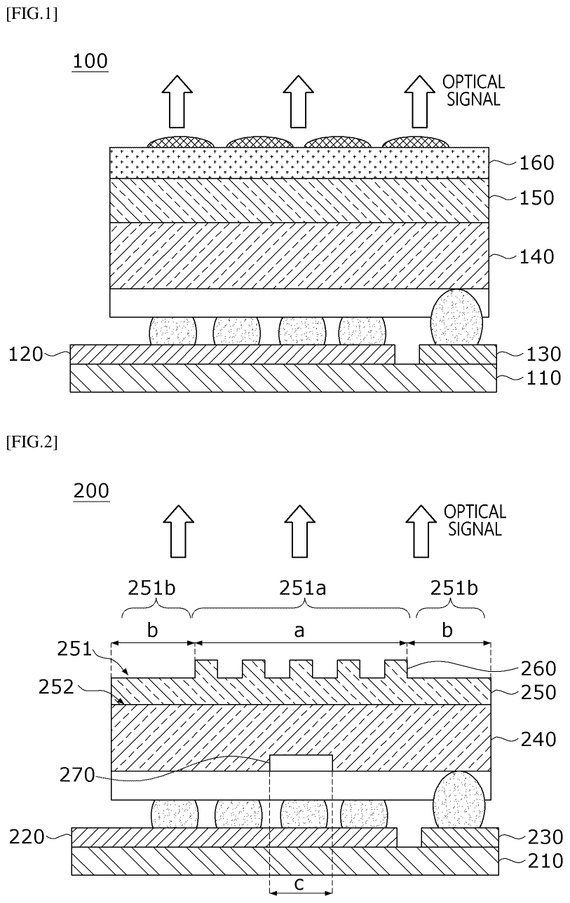

FIG. 1 is a cross-sectional view of a conventional light-emitting device.

Referring to FIG. 1, a conventional light-emitting device 100 may include a substrate 110, a first electrode 120, a second electrode 130, a light-emitting unit 140, a semiconductor substrate 150, and an optical element 160.

The conventional light-emitting device 100 may be a device that may receive electricity, convert the electricity into an optical signal, and emit light. For example, a light-emitting device 200 may be a vertical-cavity surface-emitting laser (VCSEL).

The conventional light-emitting device 100 may receive electricity from the substrate 110 through the first electrode 120 and the second electrode 130 to emit an optical signal. The optical signal may be emitted toward the semiconductor substrate 150, and the semiconductor substrate 150 may allow the optical signal to pass therethrough. The semiconductor substrate 150 may have high transmittance of the optical signa. The optical signal passing through the semiconductor substrate 150 may pass through an optical element 160 and may be emitted to the outside.

In the conventional light-emitting device 100, the first electrode 120 and the second electrode 130 may be in direct contact with the substrate 110. Since both the first electrode 120 and the second electrode 130 are disposed on a lower surface of the light-emitting unit 140 and are in direct contact with the substrate 110, the semiconductor substrate 150 and the optical element 160 may be disposed on an upper surface of the light-emitting unit 140. The conventional light-emitting device 100 has a feature in that the optical element 160 may be directly attached to the light-emitting device 100. The conventional light-emitting device 100 needs to combine a plurality of optical elements and align the optical elements on the light-emitting device 100 to change a path of the optical signal.

FIG. 2 is a cross-sectional view of a light-emitting device according to an embodiment.

Referring to FIG. 2, a light-emitting device 200 according to an embodiment may include a substrate 210, a first electrode 220, a second electrode 230, a light-emitting unit 240, a semiconductor substrate 250, a metasurface 260, and a first opening 270.

The light-emitting device 200 according to an embodiment includes the substrate 210, the first electrode 220 and the second electrode 230 that are disposed to be spaced from each other on the substrate 210, the light-emitting unit 240 that is disposed on the first electrode 220 and the second electrode 230 and is electrically connected to the first electrode 220 and the second electrode 230 and includes a first conductivity-type semiconductor layer, a light-emitting layer, and a second conductivity-type semiconductor layer, and the semiconductor substrate 250 that is disposed on the light-emitting unit 240, in which the semiconductor substrate 250 may include a first surface 251 that includes a first region 251a where a metasurface is formed, and a second surface 252 that faces the first surface 251 and is in contact with the light-emitting unit 240. The metasurface 260 protrudes in a first direction from the second surface 252 toward the first surface 251, and a second region 251b of the first surface 251, which does not include a first region 251a where the metasurface 260 is formed, may be flat. In addition, the metasurface 260 may be formed to be depressed in a second direction from the first surface 251 toward the second surface 252.

The light-emitting device 200 may be a device that may receive electricity, convert the electricity into an optical signal, and emit light. For example, the light-emitting device 200 may be a VCSEL.

In the light-emitting device 200, the light-emitting unit 240 may receive electricity from the substrate 210 through the first electrode 220 and the second electrode 230 and emit the optical signal. The optical signal may be emitted toward the semiconductor substrate 250, and the semiconductor substrate 250 may allow the optical signal to pass therethrough. The semiconductor substrate 250 may have the high transmittance of the optical signa. The optical signal passing through the semiconductor substrate 250 may pass through the metasurface 260 and may be emitted to the outside.

In the light-emitting device 200, the first electrode 220 and the second electrode 230 may be in direct contact with the substrate 210. Since both the first electrode 220 and the second electrode 230 are disposed on the lower surface of the light-emitting unit 240 and are in direct contact with the substrate 210, the semiconductor substrate 250 and the metasurface 260 may be disposed on the upper surface of the light-emitting unit 240.

The substrate 210 may be supplied with electricity and transmit the electricity to the light-emitting unit 240 through the first electrode 220 and the second electrode 230. In addition, the substrate 210 may support the light-emitting unit 240. The first electrode 220 and the second electrode 230 may be disposed in contact with the upper surface of the substrate 210.

The first electrode 220 and the second electrode 230 may be disposed to be spaced from each other on the substrate 210. The first electrode 220 and the second electrode 230 may transmit electricity between the substrate 210 and the light-emitting unit 240. The first electrode 220 and the second electrode 230 may be disposed in contact with the upper surface of the substrate 210. The first electrode 220 and the second electrode 230 may be disposed in contact with the lower surface of the light-emitting unit 240. For example, the first electrode 220 and the second electrode 230 may be a p-type metal and an n-type metal, respectively.

The light-emitting unit 240 may be supplied with electricity and generate the optical signal. The light-emitting unit 240 may include a first conductivity-type semiconductor layer, a light-emitting layer, and a second conductivity-type semiconductor layer. The light-emitting unit 240 may emit the optical signal toward the upper surface of the light-emitting unit 240 according to a difference in reflectivity of the optical signal between the first conductivity-type semiconductor layer and the second conductivity-type semiconductor layer. The light-emitting unit 240 may emit the optical signal in the first direction. The first direction may be a direction from the light-emitting unit 240 toward the semiconductor substrate 250. The first electrode 220 and the second electrode 230 may be disposed in contact with the lower surface of the light-emitting unit 240. The semiconductor substrate 250 may be disposed in contact with the upper surface of the light-emitting unit 240. The light-emitting unit 240 may include the first opening 270.

The first opening 270 may adjust an area of the optical signal emitted from the light-emitting unit 240. The first opening 270 may be disposed on a path along which the optical signal is emitted in the first direction from the light-emitting unit 240 toward the semiconductor substrate 250. The optical signal may pass through the first opening 270 to the semiconductor substrate 250 according to an area of the first opening 270 inside the light-emitting unit 240. The first opening 270 may function as an aperture of the light-emitting device 200. For example, when the area of the first opening 270 is c, the optical signal emitted from the light-emitting unit 240 may pass through the semiconductor substrate 250 by an amount corresponding to the area c.

The semiconductor substrate 250 may allow the optical signal emitted from the light-emitting unit 240 to pass therethrough. The semiconductor substrate 250 may be disposed in contact with the upper surface of the light-emitting unit 240. The semiconductor substrate 250 may include a first surface 251 and a second surface 252.

The first surface 251 may be a surface disposed in a direction opposite to the direction toward the light-emitting unit 240 of the semiconductor substrate 250. The first surface 251 may be a surface disposed in a direction in which the optical signal of the substrate 250 is emitted. The metasurface 260 may be disposed on the first surface 251. The metasurface 260 may be disposed on the first surface 251 in a form that protrudes in the first direction in which the optical signal is emitted. The first surface 251 may include the first region 251a and the second region 251b.

The first region 251a may be disposed at a center of the first surface 251. The metasurface 260 may be disposed in the first region 251a. The metasurface 260 may be disposed in the first region 251a in a form that protrudes in the first direction in which the optical signal is emitted. The optical signal passing through the semiconductor substrate 250 may be emitted to the outside to an area corresponding to a maximum area of the first region 251a. For example, when the area of the first region 251a is a, the optical signal corresponding to the area a may pass through the metasurface 260 of the first region 251a and may be emitted to the outside.

The area a of the first region 251a may be larger than an area c of the first opening 270. Since the first region 251a is a region where the optical signal passing through the opening 270 is emitted, the area a of the first region 251a may include the entire area of the optical signal passing through the opening 270.

The second region 251b may be disposed at an edge of the first surface 251. The second region 251b may be disposed in a form that surrounds the first region 251a. The second region 251b may not have a metasurface 260 disposed therein and may be flat. An area of the second region 251b may be b. The area b of the second region 251b may be smaller than the area of the first region 251a. However, the area b of the second region 251b may be larger than the area of the first region 251a.

The second surface 252 may be a surface disposed to face the light-emitting unit 240 of the semiconductor substrate 250. The second surface 252 may be disposed in a direction opposite to the first surface 251 of the semiconductor substrate 250. The second surface 252 may be a surface in contact with the light-emitting unit 240. The second surface 252 may be a surface that allows the optical signal emitted from the light-emitting unit 240 to pass through the semiconductor substrate 250.

Since the semiconductor substrate 250 transmits the optical signal, there may be high transmittance of the optical signal. The semiconductor substrate 250 according to an embodiment may include at least one of gallium arsenide (GaAs) and gallium nitride (GaN).

The metasurface 260 may change the path of the optical signal by delaying a phase of the optical signal. The metasurface 260 may be disposed on the first surface 251 of the semiconductor substrate 250. The metasurface 260 may be disposed on a part or the entirety of the first surface 251 of the semiconductor substrate 250. The metasurface 260 may be disposed on the path along which the optical signal is emitted and passes through the semiconductor substrate 250. The metasurface 260 may be disposed to include the entire region of the surface along which the optical signal passes through the semiconductor substrate 250. The metasurface 260 may be disposed on the first region 251a of the first surface 251. The metasurface 260 may be disposed across the area corresponding to the first region 251a of the first surface 251. For example, when the area of the first region 251a is a, the metasurface 260 may be disposed to be as large as the area a. The area a of the first region 251a where the metasurface 260 is disposed may be larger than the area c of the first opening 270. Since the first region 251a where the metasurface 260 is disposed is the region where the optical signal passing through the opening 270 is emitted, the area a of the first region 251a may include the entire area of the optical signal passing through the opening 270.

The metasurface 260 may implement an optical element in an ultra-thin film form in which a plurality of nano unit structures are arranged. When the optical signal passes through the metasurface, the phase of the optical signal may be delayed to change the path of the optical signal. When the metasurface is used, the total thickness of the plurality of optical elements may be reduced from several mm to less than 1 μm, thereby improving the performance of the optical module.

The metasurface 260 according to an embodiment may protrude in the first direction from the second surface 252 toward the first surface 251. The metasurface 260 may protrude in the first direction on the first surface 251 of the semiconductor substrate 250 to replace the optical element. The metasurface 260 may be formed by etching the surface of a semiconductor substrate 250.

The light-emitting unit 240 according to an embodiment may include the first opening 270 that controls the area of the optical signal emitted in the first direction, and the area a of the metasurface 260 may be larger than the area c of the first opening 270.

The first opening 270 may adjust the area of the optical signal emitted from the light-emitting unit 240. The first opening 270 may be disposed on the path along which the optical signal is emitted in the first direction from the light-emitting unit 240 toward the semiconductor substrate 250. The optical signal may pass through the first opening 270 to the semiconductor substrate 250 according to the area of the first opening 270 inside the light-emitting unit 240. The first opening 270 may function as an aperture of the light-emitting device 200. For example, when the area of the first opening 270 is c, the optical signal emitted from the light-emitting unit 240 may pass through the semiconductor substrate 250 by the amount corresponding to the area c. The area a of the first region 251a may be larger than the area c of the first opening 270. Since the first region 251a is the region where the optical signal passing through the opening 270 is emitted, the area a of the first region 251a may include the entire area of the optical signal passing through the opening 270.

The metasurface 260 according to an embodiment may be formed in the first direction in which the optical signal is emitted. The metasurface 260 may protrude in the first direction on the first surface 251 of the semiconductor substrate 250 to replace the optical element. The metasurface 260 may be formed to protrude in the first direction on the first surface 251 exposed to the outside of the semiconductor substrate 250 and thus formed by etching the surface of the semiconductor substrate 250 without a separate additional process in the manufacturing process of the light-emitting device 200.

The metasurface 260 according to an embodiment includes the plurality of unit structures, and the phase of the optical signal may be delayed by the plurality of unit structures. The metasurface 260 may be composed of the plurality of nano unit structures, and the unit structures may have different diameters, heights, shapes, materials, etc. depending on the function of the optical element to be implemented. The unit structures of the metasurface 260 may have different diameters, and thus the phase of the optical signal after the optical signal passes through the unit structures may change in a different manner.

The plurality of unit structures according to an embodiment may include a plurality of circular cylinders or a plurality of quadrangular pillars protruding in the first direction from the first surface 251.

A design method of the unit structure according to the embodiment may be an isotropic, anisotropic, birefringent, polarization-dependent, or polarization-independent design.

The light-emitting device 200 according to an embodiment may be a vertical-cavity surface-emitting laser having a flip chip structure.

In the case of the flip chip structure, the light-emitting device 200 may be fabricated by arranging the electrodes between the light-emitting unit 240 of the light-emitting device 200 and the substrate 210 and on one surface of the light-emitting device and by arranging the optical element on the other surface of the light-emitting device. Therefore, the metasurface 260 of the light-emitting device 200 according to an embodiment may be disposed on the semiconductor substrate 250, which is a surface opposite to the surface on which the electrode of the light-emitting device 200 having the flip-chip structure is disposed.

The semiconductor substrate 250 according to an embodiment may include at least one of GaAs and GaN.

Since the semiconductor substrate 250 allows the optical signal emitted from the light-emitting unit 240 to pass therethrough, there may be high optical transmittance of the semiconductor substrate 250. The semiconductor substrate 250 may include at least one of GaAs and GaN having high optical transmittance. The metasurface 260 may be made of a heterostructure material.

The metasurface 260 according to an embodiment may be formed by micro electro mechanical systems (MEMS).

The metasurface 260 according to an embodiment may perform at least one of focusing, diverging, and diffracting of the optical signal emitted from the light-emitting unit.

The metasurface 260 according to an embodiment may focus the optical signal emitted from the light-emitting unit. The metasurface 260 may function as a focusing lens that focuses the optical signal emitted from the light-emitting unit 240. The metasurface 260 according to an embodiment may diverge the optical signal emitted from the light-emitting unit 240. The metasurface 260 according to an embodiment may function as a lens that diverges the optical signal emitted from the light-emitting unit 240. The metasurface 260 according to an embodiment may diffract the optical signal emitted from the light-emitting unit 240. The metasurface 260 may function as a diffractive optical element (DOE) that diffracts the optical signal emitted from the light-emitting unit 240.

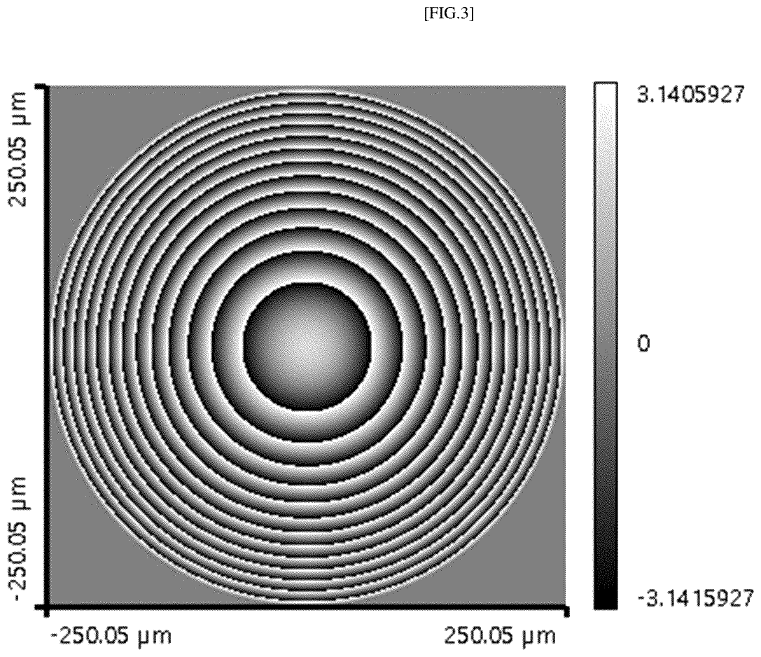

FIG. 3 is a phase diagram of the metasurface of the light-emitting device according to an embodiment.

A phase diagram may be derived to implement the light-emitting device according to an embodiment to have the metasurface. The phase diagram is derived based on the performance and effect of the corresponding optical element and represents the phase of the optical signal according to the position where the optical signal passes through the optical element.

Referring to FIG. 3, the phase diagram of a collimator, which is the optical element, may be represented as provided in FIG. 3.

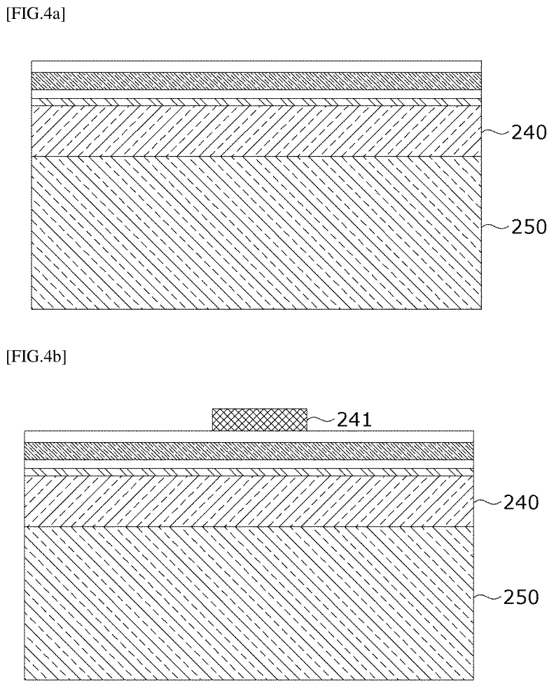

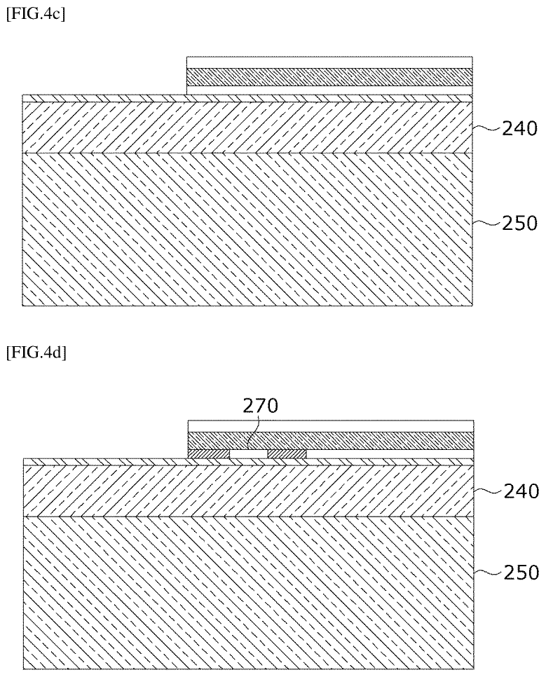

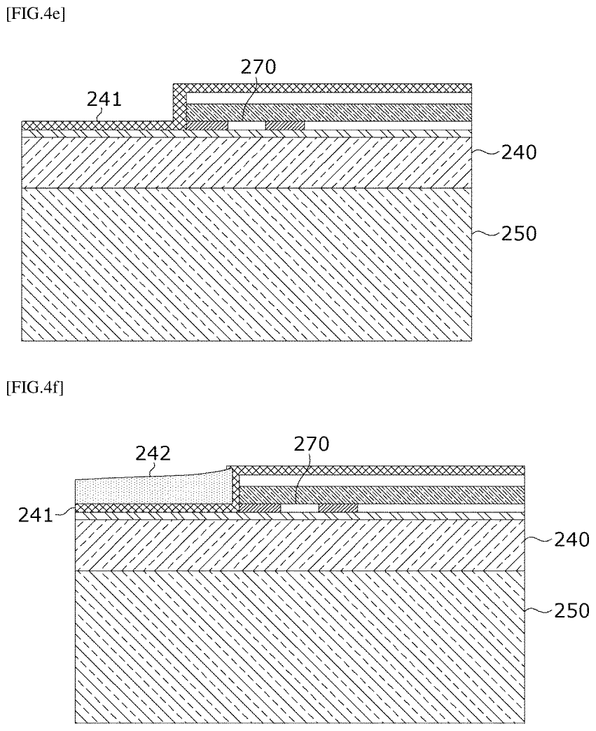

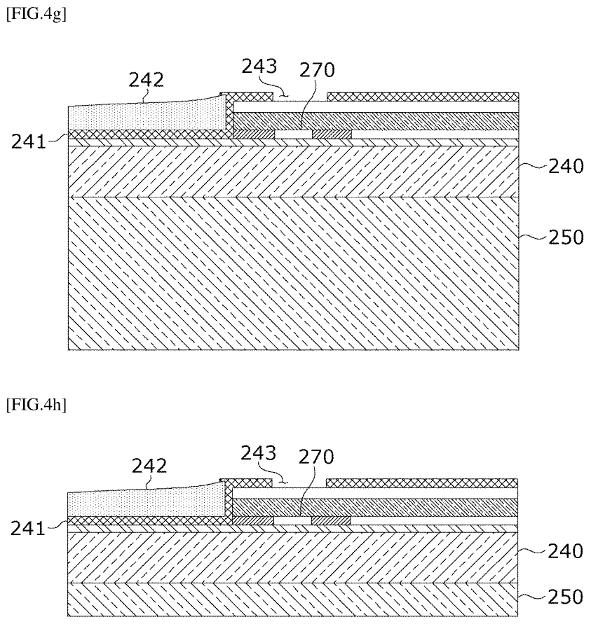

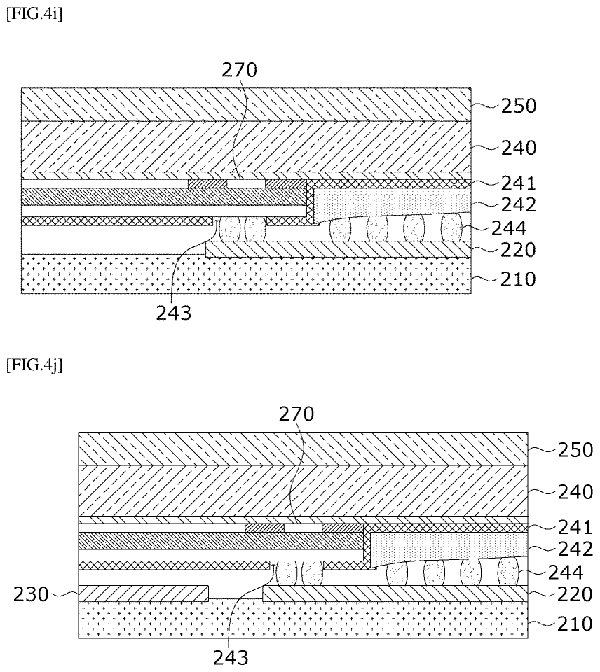

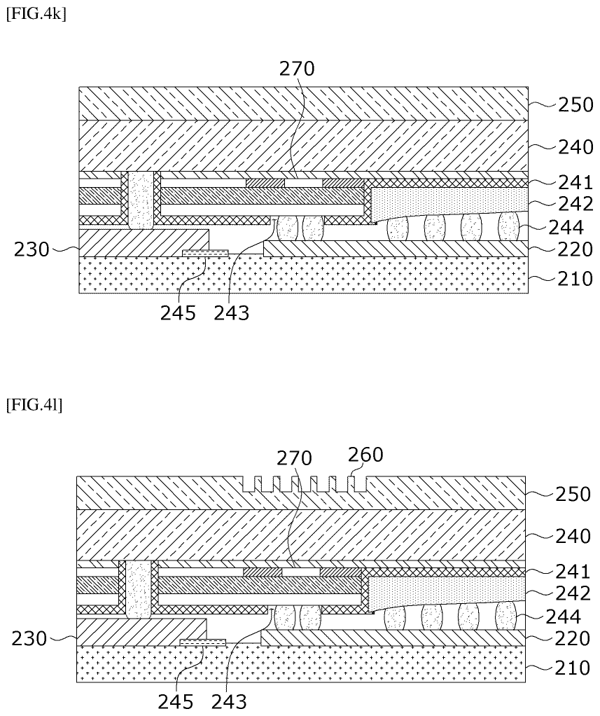

FIGS. 4A to 4L are cross-sectional views of the light-emitting device according to a process of the light-emitting device according to an embodiment.

Referring to FIGS. 4A to 4L, the light-emitting device according to the embodiment may be formed by the MEMS. Referring to FIGS. 4A to 4L, the light-emitting device according to an embodiment may be formed by the MEMS according to the order of FIGS. 4A to 4L.

FIG. 4A illustrates an epitaxial growth of the light-emitting device.

Referring to FIG. 4A, the light-emitting device may be formed using metal organic chemical vapor deposition (MOCVD) or molecular beam epitaxy (MBE) in terms of the epitaxial growth for forming the light-emitting device. In the present embodiment, GaAs is used, but it can be applied to various heterojunction structures such as GaN, InGaAlP, and others. The light-emitting unit 240 may be formed on the semiconductor substrate 250.

FIG. 4B illustrates a deposition SiO2 mask of the light-emitting device.

Referring to FIG. 4B, when performing mesa etching of FIG. 4C, a dielectric such as SiO2 or a metal may be used as a means for selectively performing epitaxial etching. A SiO2 mask 241 may be formed on the semiconductor substrate 250 and the light-emitting unit 240.

FIG. 4C illustrates mesa etching and SiO2 removal of the light-emitting device.

Referring to FIG. 4C, the mesa etching is performed using reactive ion etching (RIE) or ion coupled plasma (ICP)-RIE. Thereafter, the SiO2 mask used as a deposition mask is removed by wet etching or ashing. A part of the light-emitting unit 240 may be mesa etched, and the SiO2 mask 241 may be removed.

FIG. 4D illustrates aperture oxidation of the light-emitting device.

Referring to FIG. 4D, the first opening 270 may be formed in a part of the inside of the light-emitting unit 240.

FIG. 4E illustrates SiO2 passivation of the light-emitting device.

Referring to FIG. 4E, the SiO2 passivation 241 may be formed on the surface of the mesa-etched light-emitting unit 240.

FIG. 4F illustrates benzocyclobutene (BCB) spin coating and etching of the light-emitting device.

Referring to FIG. 4F, coating and etching of BCB spin 242 may be performed on a part of the SiO2 passivation 241.

FIG. 4G illustrates SiO2 passivation for opening of a layer of the light-emitting device.

Referring to FIG. 4G, a second opening 243 may be formed in a part of the SiO2 passivation 241. The second opening 243 may be a portion through which the light-emitting unit 240 is in contact with the electrode.

Referring to FIGS. 4D to 4G, these show a process for forming an opening of an epitaxial semiconductor laser, and the opening of the laser may be formed depending on the size of the SiO2 layer that is removed when the process of FIGS. 4F to 4G is performed. This may be a factor that determines the quality of the output laser beam (beam parameter product (BPP)).

FIG. 4H illustrates n-GaAs layer thinning of the light-emitting device.

Referring to FIG. 4H, the thinning of n-GaAs may be performed to avoid loss of light efficiency due to absorption, internal reflection, etc., of the semiconductor substrate 250 when implementing the flip-chip structure of the semiconductor laser.

FIG. 4I illustrates P-electrode and bump fabrication of the light-emitting device.

Referring to FIG. 4I, a plurality of bumps 244 in contact with the light-emitting unit 240 through a BCB spin 242 or the second opening 243 may be formed, and the first electrode 220 and the substrate 210 in contact with the plurality of bumps 244 may be formed.

FIG. 4I illustrates n-electrode fabrication of the light-emitting device.

Referring to FIG. 4I, the second electrode 230 in contact with the substrate 210 may be formed.

FIG. 4K illustrates n-electrode and via filling fabrication of the light-emitting device.

Referring to FIG. 4K, a via filling 245 in contact with the second electrode 230 and the substrate 210 may be formed, and the second electrode 230 may be in contact with the light-emitting unit.

Referring to FIGS. 4I to 4K, it may correspond to a process of forming an electrode that supplies an electrical pumping source for oscillation of the light-emitting device having the implemented flip-chip structure.

FIG. 4I illustrates integration of the metasurface of the light-emitting device.

Referring to FIG. 4I, this may show a process of forming the metasurface 260 on a surface used as the semiconductor substrate 250 of the light-emitting device structure in the form of the flip chip.

Here, when selecting the semiconductor substrate 250 used for forming the metasurface 260, a refractive index (n) and an extinction coefficient (k) may be considered for selection. The measurement of these values may be obtained through spectroscopic ellipsometry.

Referring to FIG. 4I, GaAs used as the semiconductor substrate 250 of an embodiment has a high refractive index of n=3.506 and a low extinction coefficient of k=0.009 at an operating wavelength of 940 nm. These characteristics may indicate that GaAs is a material suitable for all dielectric metasurfaces in an IR region.

The process of forming the GaAs-based metasurface 260 of the above-described embodiment is as follows. First, PMMA, which is to be used as a photosensitive agent, is applied by performing spin coating on the GaAs substrate. Thereafter, patterning is performed using a mask having the shape of the designed metasurface 260 using e-beam lithography, and then development is performed. Then, selective etching of the GaAs substrate to which a photoresist is selectively applied is performed using reactive ion etching (RIE) or ion coupled plasma (ICP)-RIE. Finally, the metasurface 260 according to an embodiment is implemented by removing the PMMA layer.

The metasurface according to an embodiment may be formed on the semiconductor substrate at the end of the MEMS process of the light-emitting device.

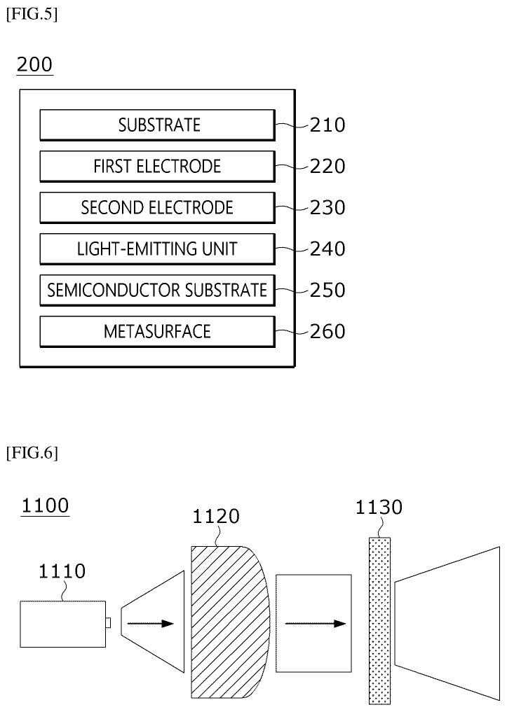

FIG. 5 is a configuration diagram of the light-emitting device according to an embodiment.

Referring to FIG. 5, the light-emitting device 200 according to the embodiment may include the substrate 210, the first electrode 220, the second electrode 230, the light-emitting unit 240, the semiconductor substrate 250, the metasurface 260, and the first opening 270.

FIG. 6 is a conceptual diagram of a conventional optical module.

Referring to FIG. 6, a conventional optical module 1100 may include a light-emitting unit 1110, a first optical unit 1120, and a second optical unit 1130. The conventional optical module 1100 of FIG. 6 is for comparison with an optical module 1200 according to an embodiment of the present invention, and an embodiment of the present invention is not limited thereto.

The light-emitting unit 1110 may radiate the optical signal.

The first optical unit 1120 and the second optical unit 1130 may be optical elements that change a phase of the optical signal, such as a collimating lens, a DOE, a phase plate, and a focusing lens.

The conventional optical module 1100 may allow the optical signal radiated by the light-emitting unit 1110 to pass through the plurality of optical units, thereby changing the optical signal to the desired path, arrangement, etc. For example, the first optical unit 1120 may be a collimator, and the second optical unit 1130 may be a DOE. The optical signal emitted from the light-emitting unit 1110 of the conventional optical module 1100 may be emitted after passing through the first optical unit 1120 and then passing through the second optical unit 1130.

The light-emitting unit 1110, the first optical unit 1120, and the second optical unit 1130 may be disposed to be spaced a predetermined interval from each other. For example, the light-emitting unit 1110 and the first optical unit 1120 may be disposed to be spaced a first interval from each other, and the first optical unit 1120 and the second optical unit 1130 may be disposed to be spaced a second interval from each other. In order to adjust the optical signal emitted from the second optical unit 1130, the locations of the light-emitting unit 1110, the first optical unit 1120, and the second optical unit 1130 may be adjusted, and thus, a space is required to accommodate the light-emitting unit 1110, the first optical unit 1120, and the second optical unit 1130.

That is, since the plurality of optical units are combined and disposed in the conventional optical module 1100, the conventional optical module 1100 requires a thickness or volume of a certain level or more.

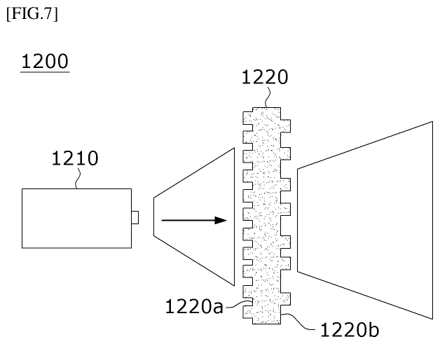

FIG. 7 is a conceptual diagram of the optical module according to an embodiment.

Referring to FIG. 7, the optical module 1200 according to the embodiment may include a light-emitting unit 1210 and an optical unit 1220.

The light-emitting unit 1210 may radiate the optical signal.

The optical unit 1220 may include metasurfaces that function as optical elements that change the phase of the optical signal, such as a collimating lens, a DOE, a phase plate, and a focusing lens. In other words, the optical unit 1220 may perform multiple functions simultaneously. For example, the optical signal passing through the optical unit 1220 may perform at least two functions among the collimating lens, the DOE, the phase plate, and the focusing lens. This may be performed by a first surface 1220a and a second surface 1220b corresponding to different surfaces of the optical unit 1220. Here, the first surface 1220a and the second surface 1220b may correspond to different metasurfaces.

The first surface 1220a of the optical unit 1220 may protrude toward the light-emitting unit 1210, and the second surface 1220b may protrude in a direction opposite to the direction toward the light-emitting unit 1210. That is, the metasurface of the first surface 1220a and the metasurface of the second surface 1220b may protrude in different directions.

The optical signal passing through the first surface 1220a may have its phase changed by the metasurface and may have a different phase from the optical signal output from the light-emitting unit 1210. In addition, the optical signal passing through the second surface 1220b may have its phase changed by the metasurface and may have a different phase from the optical signal passing through the first surface 1220a. Here, the optical signal having a different phase may be a characteristic of the optical signal corresponding to one of the functions of the plurality of optical elements.

A protrusion of the first surface 1220a and a protrusion of the second surface 1220b may protrude in the same direction. However, the protrusion of the first surface 1220a and the protrusion of the second surface 1220b may protrude in different directions, not in the same direction or opposite directions. In addition, the protrusions of the first surface 1220a and the second surface 1220b may have different diameters, locations, heights, etc.

The optical unit 1220 according to an embodiment may include metasurfaces disposed on both surfaces of a single substrate.

The optical module 1200 according to an embodiment may allow an optical signal radiated by the light-emitting unit 1210 to pass through the plurality of metasurfaces to change the optical signal to the desired path, arrangement, etc. For example, the first surface 1220a may correspond to the collimator, and the second surface 1220b may correspond to the DOE. The optical signal emitted from the light-emitting unit 1210 of the conventional optical module 1200 may be emitted after passing through the first surface 1220a and then the second surface 1220b.

The metasurface may implement the optical element in the ultra-thin film form in which the plurality of nano-unit structures are arranged. When the optical signal passes through the metasurface, the phase of the optical signal may be delayed to change the path of the optical signal. When the metasurface is used, the total thickness of the plurality of optical elements may be reduced from several mm to 1 μm or less, thereby improving the performance of the optical module.

The optical unit 1220 according to an embodiment may be formed by implementing both surfaces of a single substrate to have the metasurface. When two metasurfaces are disposed on a single substrate, the functions of two optical elements may be implemented with one substrate, and thus the total thickness of the optical element may be further reduced. Accordingly, the volume of the optical module 1200 including the optical unit 1220 may be further reduced.

In addition, the optical module 1200 may include the optical unit 1220 having multiple functions, thereby providing the optical module 1200 with reduced weight.

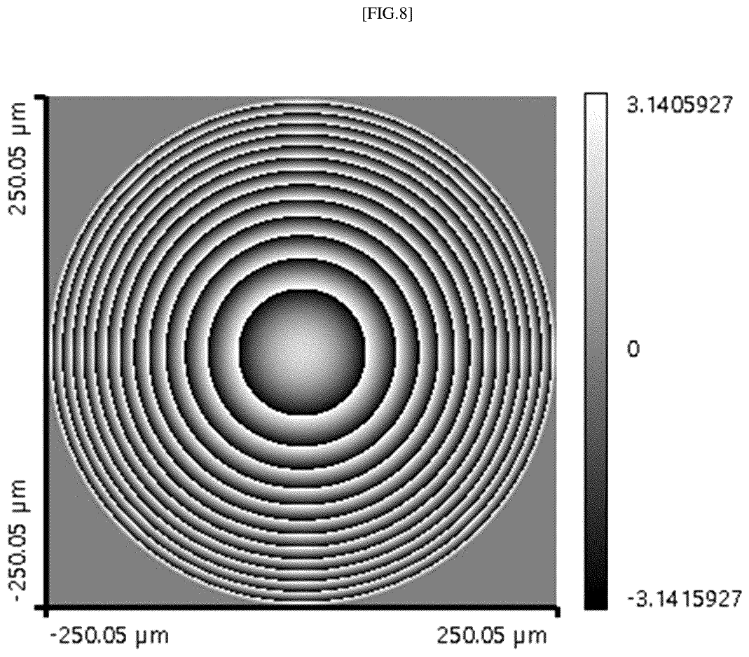

FIG. 8 is the phase diagram in which the optical system according to an embodiment is implemented with a metasurface.

In order to implement the optical unit according to an embodiment to have the metasurface, the phase diagram of the optical unit may be derived. The phase diagram is derived based on the performance and effect of the corresponding optical element and represents the phase of the optical signal according to the position where the optical signal passes through the optical element.

Referring to FIG. 8, the phase diagram of the collimator, which is the optical element, may be represented as provided in FIG. 8.

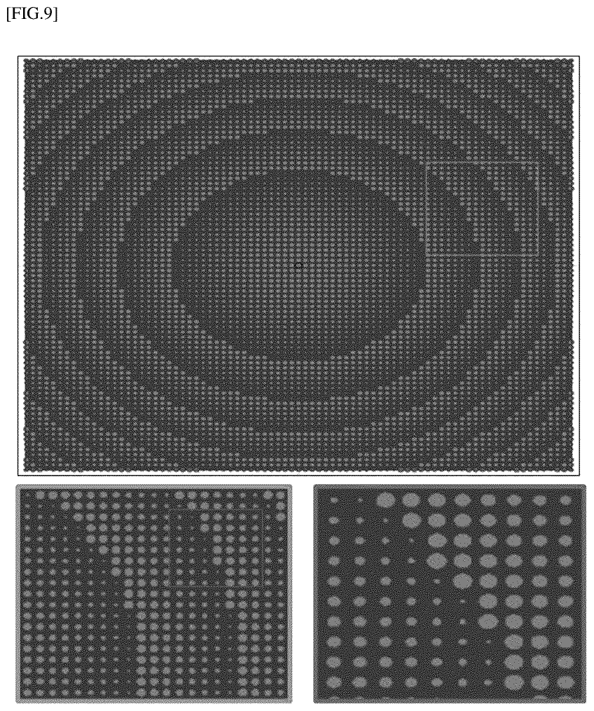

FIG. 9 is an image illustrating the unit structure of the metasurface according to an embodiment.

The metasurface may be composed of the plurality of nano unit structures, and the unit structures may have different diameters, heights, shapes, materials, etc., depending on the function of the optical element to be implemented.

Referring to FIG. 9, the unit structures of the metasurface according to an embodiment may have different diameters to change the phase of the optical signal after the optical signal passes through the unit structure.

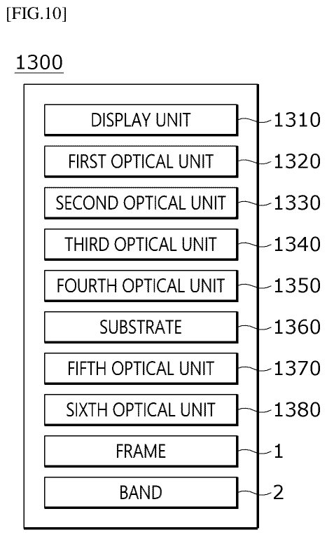

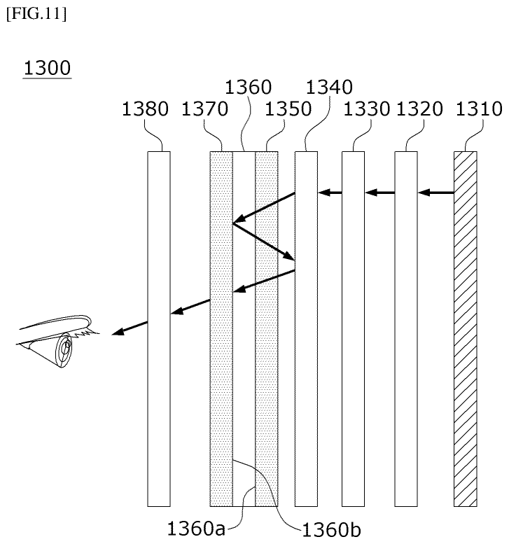

FIG. 10 is a configuration diagram of a VR module according to an embodiment.

Referring to FIG. 10, a VR module 1300 according to the embodiment may include a display unit 1310, a first optical unit 1320, a second optical unit 1330, a third optical unit 1340, a fourth optical unit 1350, a substrate 1360, a fifth optical unit 1370, and a sixth optical unit 1380.

The VR module 1300 may be an optical module that may be optimized for playing and viewing images, etc., in a virtual world rather than in an actual space. The VR module 1300 may include the display unit 1310 that transmits images and the like, the optical system including the plurality of optical units, a frame 1 that fixes the display unit 1310 and the optical system on the outside, and a band 2 that may fix the VR module 1300 to an observer. The optical signal such as an image transmitted from the display unit 1310 may pass through the optical system including the plurality of optical elements and may be incident on an observer's eyes. The frame 1 includes an opening, and the optical signal passing through the optical system may be incident on the observer's eyes through the opening, and the frame 1 may be fixed on the observer's eyes through the band 2. It may be a method of fixing the frame 1 in front of the observer's eyes by wrapping the band 2 around the observer's head.

The display unit 1310 may radiate the optical signal.

The display unit 1310 may be a display panel that radiates the optical signal and may output image information of the VR module. The type, size, or resolution of the display unit 1310 is not limited. For example, the display unit 1310 may include a liquid crystal display (LCD), an organic light-emitting diode (OLED), an OLED on silicon (OLEDoS), or a micro light-emitting diode (MicroLED). In addition, for example, the size of the display unit 1310 may be 6.225 cm 5.75 cm, and the resolution may be 1170 pixels*1080 pixels.

The first to sixth optical units 1320, 1330, 1340, 1350, 1370, and 1380 may be optical elements that change the phase of the optical signal output from the display unit 1310. The first to sixth optical units 1320, 1330, 1340, 1350, 1370, and 1380 may be collectively referred to as an optical system. By including the plurality of optical units corresponding to the first to sixth optical units 1320, 1330, 1340, 1350, 1370, and 1380 in the optical system, there is an effect of reducing a focal distance between the image of the VR module and the user. That is, by using the first to sixth optical units 1320, 1330, 1340, 1350, 1370, and 1380, the VR module 1300 may be made lightweight and compact.

The substrate 1360 may be a substrate that may allow the optical signal to pass therethough. Since the substrate 1360 should be able to allow the optical signal to pass therethrough, there may be high transmittance of light.

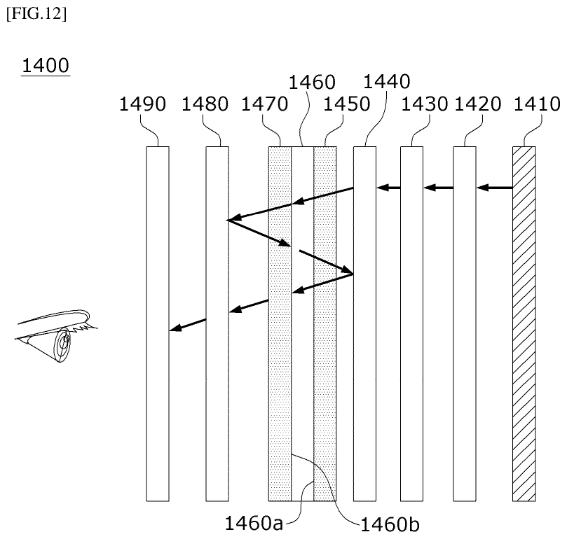

Hereinafter, the optical elements included in the VR module 1300 will be described with reference to FIGS. 11 and 12.

FIG. 11 is a conceptual diagram of the VR module according to an embodiment.

Referring to FIG. 11, the VR module 1300 according to the embodiment includes the display unit 1310 that radiates the optical signal, the optical system including the first to sixth optical units 1320, 1330, 1340, 1350, 1370, and 1380 that are sequentially disposed on the path of the optical signal, and the substrate 1360 that is disposed between the fourth optical unit 1350 and the fifth optical unit 1370, in which the display unit 1310 and the first to sixth optical units 1320, 1330, 1340, 1350, 1370, and 1380 are disposed to be spaced a predetermined interval from each other, the fourth optical unit 1350 focuses the optical signal, the fifth optical unit 1370 delays the phase of the optical signal, and at least one of the fourth optical unit 1350 and the fifth optical unit 1370 may be a metasurface disposed on one surface of the substrate 1360.

The display unit 1310 may radiate the optical signal. The display unit 1310 may radiate the optical signal to the first optical unit 1320. The display unit 1310 may be disposed in the first direction. The display unit 1310 may be a display panel that radiates the optical signal and may output image information of the VR module. The display unit 1310 may include an LCD, an OLED, an OLEDOS, or a MicroLED.

The first to sixth optical units 1320, 1330, 1340, 1350, 1370, and 1380 may be optical elements that change the phase of the optical signal, such as a collimating lens, a DOE, a phase plate, and a focusing lens. The first to sixth optical units 1320, 1330, 1340, 1350, 1370, and 1380 may be disposed to be spaced a predetermined interval from each other in the second direction perpendicular to the first direction on the path of the optical signal radiated from the display unit 1310, and each of the first to sixth optical units 1320, 1330, 1340, 1350, 1370, and 1380 may be disposed in the same first direction as the display unit 1310. The first to sixth optical units 1320, 1330, 1340, 1350, 1370, and 1380 may be disposed to be spaced a predetermined interval from each other or disposed to be spaced apart from each other at different intervals. A space between the first to sixth optical units 1320, 1330, 1340, 1350, 1370, and 1380 is an empty space, and air may serve as an intermediate medium for the optical signal. The first to sixth optical units 1320, 1330, 1340, 1350, 1370, and 1380 may collectively be referred to as the optical system. Each of the first to sixth optical units 1320, 1330, 1340, 1350, 1370, and 1380 may be an optical element in the form of a thin film or a flat plate. In addition, the first to sixth optical units 1320, 1330, 1340, 1350, 1370, and 1380 are optical elements with a predetermined thickness and are disposed to be spaced a predetermined interval from each other, and thus a certain space is required for accommodation thereof. By including the plurality of optical units corresponding to the first to sixth optical units 1320, 1330, 1340, 1350, 1370, 1380 and 1380 in the optical system, there is an effect of reducing a focal distance between the image of the VR module and the user.

The first optical unit 1320 may allow the optical signal radiated from the display unit 1310 to pass therethrough. The first optical unit 1320 may be disposed to be spaced a predetermined interval from the display unit 1310, and the first optical unit 1320 may be disposed parallel to the display unit 1310. The first optical unit 1320 may be disposed between the display unit 1310 and the second optical unit 1330.

The first optical unit 1320 according to an embodiment may be a linear polarizer that transmits a P wave of the optical signal. The first optical unit 1320 may transmit only a P wave polarization of the optical signal radiated from the display unit 1310 and may reflect an S wave polarization.

The second optical unit 1330 may allow the optical signal that has passed through the first optical unit 1320 to pass therethrough. The second optical unit 1330 may be disposed to be spaced a predetermined distance from the first optical unit 1320, and the second optical unit 1330 may be disposed parallel to the first optical unit 1320. The second optical unit 1330 may be disposed between the first optical unit 1320 and the third optical unit 1340.

The second optical unit 1330 according to an embodiment may be a wave plate that delays the phase of the optical signal by ¼ wavelength. The second optical unit 1330 may delay the phase of the optical signal passing through the first optical unit 1320 by ¼ wavelength relative to the phase of the optical signal prior to passing through the first optical unit 1320.

The second optical unit 1330 according to an embodiment may be a metasurface that delays the phase of the optical signal by ¼ wavelength.

The third optical unit 1340 may allow the optical signal that has passed through the second optical unit 1330 to pass therethrough. The third optical unit 1330 may be disposed to be spaced a predetermined distance from the second optical unit 1330, and the third optical unit 1340 may be disposed parallel to the second optical unit 1330. The third optical unit 1340 may be disposed between the second optical unit 1330 and the fourth optical unit 1350.

The third optical unit 1340 according to an embodiment may be a partially reflective mirror that transmits 50% of the optical signal. The third optical unit 1340 may transmit 50% of the optical signal that has passed through the second optical unit 1330 and reflect 50% of the optical signal.

The fourth optical unit 1350 may allow the optical signal that has passed through the third optical unit 1340 to pass therethrough. The fourth optical unit 1350 may be disposed to be spaced a predetermined distance from the third optical unit 1340, and the fourth optical unit 1350 may be disposed parallel to the third optical unit 1340. The fourth optical unit 1350 may be disposed between the third optical unit 1340 and the substrate 1360.

The fourth optical unit 1350 according to an embodiment may focus the optical signal. The fourth optical unit 1350 may focus the optical signal that has passed through the third optical unit 1340. For example, the fourth optical unit 1350 may be a lens that focuses the optical signal on a focal point at a certain distance.

The fourth optical unit 1350 according to an embodiment may be a metasurface disposed on one surface of the substrate 1360. The fourth optical unit 1350 may be formed by etching the surface of the substrate 1360. The metasurface of the fourth optical unit 1350 may implement an optical element that performs a focusing function in an ultra-thin film form in which a plurality of nano-unit structures are arranged. When the optical signal passes through the metasurface, the phase of the optical signal may be delayed to change the path of the optical signal. When the metasurface is used, the total thickness of the plurality of optical elements may be reduced from several mm to 1 μm or less, thereby improving the performance of the optical module.

The fourth optical unit 1350 may be disposed on a first surface 1360a of the substrate 1360. The first surface 1360a may be disposed to face the third optical unit 1340 of the substrate 1360. The fourth optical unit 1350 may be a metasurface formed by etching the first surface 1360a of the substrate 1360. The fourth optical unit 1350 may be an optical element formed by coating the first surface 1360a of the substrate 1360.

The substrate 1360 may allow the optical signal that has passed through the fourth optical unit 1350 to pass therethrough. The substrate 1360 may be disposed to be spaced a predetermined distance from the fourth optical unit 1350, and the substrate 1360 may be disposed parallel to the fourth optical unit 1350. The substrate 1360 may be disposed between the fourth optical unit 1350 and the fifth optical unit 1370. The substrate 1360 may include the first surface 1360a and a second surface 1360b. The first surface 1360a may be a surface facing the fourth optical unit 1350 of the substrate 1360, and the second surface 1360b may be a surface facing the fifth optical unit 1370 of the substrate 1360.

The substrate 1360 according to an embodiment may be a GaAs substrate. The substrate 1360 may be a substrate that may allow the optical signal to pass therethrough. Since the substrate 1360 should be able to allow the optical signal to pass therethrough, there may be high transmittance of light.

The fourth optical unit 1350 or the fifth optical unit 1370 may be disposed on one surface of the substrate 1360. The fourth optical unit 1350 may be disposed on the first surface 1360a of the substrate 1360, and the fifth optical unit 1370 may be disposed on the second surface 1360b of the substrate 1360.

At least one of the fourth optical unit 1350 and the fifth optical unit 1370 may be a metasurface disposed on one surface of the substrate 1360. The metasurface of the fourth optical unit 1350 or the fifth optical unit 1370 may be formed by etching the surface of the substrate 1360. The fourth optical unit 1350 or the fifth optical unit 1370 may be a metasurface etched on the first surface 1360a or the second surface 1360b of the substrate 1360.

In addition, the fourth optical unit 1350 or the fifth optical unit 1370 may be disposed by being applied on one surface of the substrate 1360. When the fourth optical unit 1350 or the fifth optical unit 1370 is disposed by being applied on one surface of the substrate 1360, the fourth optical unit 1350 or the fifth optical unit 1370 may be an optical element other than the metasurface. The fourth optical unit 1350 or the fifth optical unit 1370 may be an optical element applied on the first surface 1360a or the second surface 1360b of the substrate 1360.

The fifth optical unit 1370 may allow the optical signal passing through the substrate 1360 to pass therethrough. The fifth optical unit 1370 may be disposed to be spaced a predetermined distance from the substrate 1360, and the fifth optical unit 1370 may be disposed parallel to the substrate 1360. The fifth optical unit 1370 may be disposed between the substrate 1360 and the sixth optical unit 1380.

The fifth optical unit 1370 according to an embodiment may delay the phase of the optical signal by half a wavelength. The fifth optical unit 1370 may delay the phase of the optical signal passing through the substrate 1360 by half a wavelength. For example, the fifth optical unit 1370 may be a half-wave delay wave plate.

The fifth optical unit 1370 according to an embodiment may be a metasurface disposed on one surface of the substrate 1360. The fifth optical unit 1370 may be formed by etching the surface of the substrate 1360. The metasurface of the fifth optical unit 1370 may implement the optical element that delays the phase of the optical signal by half a wavelength in the ultra-thin film form in which the plurality of nano-unit structures are arranged. When the optical signal passes through the metasurface, the phase of the optical signal may be delayed to change the path of the optical signal. When the metasurface is used, the total thickness of the plurality of optical elements may be reduced from several mm to 1 μm or less, thereby improving the performance of the optical module.

The fifth optical unit 1370 may be disposed on the second surface 1360b of the substrate 1360. The second surface 1360b may be disposed to face the sixth optical unit 1380 of the substrate 1360. The fifth optical unit 1370 may be a metasurface formed by etching the second surface 1360b of the substrate 1360. The fifth optical unit 1370 may be an optical element formed by coating the second surface 1360b of the substrate 1360.

The fifth optical unit 1370 according to an embodiment may reflect a first circularly polarized light of the optical signal and allow a second circularly polarized light whose phase is delayed by half a wavelength relative to the phase of the first circularly polarized light to pass therethrough.

The first circularly polarized light may be the circularly polarized light of the optical signal whose phase of the optical signal is not delayed by half a wavelength, and the second circularly polarized light may be the circularly polarized light of the optical signal whose phase of the optical signal is delayed by half a wavelength due to passing through the fifth optical unit 1370.

The sixth optical unit 1380 according to an embodiment may allow the optical signal that has passed through the fifth optical unit 1370 to pass therethrough. The sixth optical unit 1380 may be disposed to be spaced a predetermined distance from the fifth optical unit 1370, and the sixth optical unit 1380 may be disposed parallel to the fifth optical unit 1370. An observer may identify the optical signal passing through the sixth optical unit 1380.

The sixth optical unit 1380 according to an embodiment may be a linear polarizer that transmits the S wave of the optical signal. The sixth optical unit 1380 may transmit only the S wave polarization of the optical signal passing through the fifth optical unit 1370 and reflect the P wave polarization.

At least one of the fourth optical unit 1350 and the fifth optical unit 1370 according to an embodiment may be a metasurface that is disposed on one surface of the substrate 1360.

One of the fourth optical unit 1350 and the fifth optical unit 1370 may be a metasurface disposed on one surface of the substrate 1360, while the other may be an optical element formed by being applied on one surface of the substrate 1360. For example, the fourth optical unit 1350 may be a metasurface that focuses an optical signal disposed on one surface of the substrate 1360, and the fifth optical unit 1370 may be an optical element that delays the phase of the optical signal by being applied on the other surface of the substrate 1360. In addition, for example, the fourth optical unit 1350 may be an optical element that focuses the optical signal by being applied on one surface of the substrate 1360, and the fifth optical unit 1370 may be a metasurface that delays the phase of the optical signal by being applied on the other surface of the substrate 1360 by half a wavelength.

The fourth optical unit 1350 according to an embodiment may be a metasurface disposed on the surface of the substrate 1360 facing the third optical unit 1340, and the fifth optical unit 1370 may be a metasurface disposed on the surface of the substrate 1360 facing the sixth optical unit 1380.

The fourth optical unit 1350 and the fifth optical unit 1370 may be metasurfaces disposed on different surfaces of the substrate 1360. The fourth optical unit 1350 and the fifth optical unit 1370 may be disposed on two different surfaces spaced apart from each other on the path along which the optical signal passes through the substrate 1360.

The fourth optical unit 1350 may be disposed between the substrate 1360 and the third optical unit 1340. In addition, the fourth optical unit 1350 may be disposed parallel to the substrate 1360 or the third optical unit 1340 and may be disposed to be spaced a predetermined distance from the substrate 1360 or the third optical unit 1340. The fourth optical unit 1350 may be disposed to be spaced a predetermined distance from the third optical unit 1340, and the fourth optical unit 1350 may be a metasurface disposed on the surface of the substrate 1360 facing the third optical unit 1340. The fourth optical unit 1350 is formed on the surface of the substrate 1360 to face the third optical unit 1340, and thus the optical signal passing through the third optical unit 1340 may pass through the metasurface of the fourth optical unit 1350.

The fifth optical unit 1370 may be disposed between the substrate 1360 and the sixth optical unit 1380. In addition, the fifth optical unit 1370 may be disposed parallel to the substrate 1360 or the sixth optical unit 1380 and may be disposed to be spaced a predetermined distance from the substrate 1360 or the sixth optical unit 1380. The fifth optical unit 1370 may be disposed to be spaced a predetermined distance from the sixth optical unit 1380, and the fifth optical unit 1370 may be the metasurface disposed on the surface of the substrate 1360 facing the sixth optical unit 1380. The fifth optical unit 1370 is formed on the surface of the substrate 1360 to face the sixth optical unit 1380, and thus the optical signal passing through the metasurface of the fifth optical unit 1370 may pass through the sixth optical unit 1380.

The optical signal according to an embodiment may sequentially pass through the display unit 1310, the first optical unit 1320, the second optical unit 1330, the third optical unit 1340, the fourth optical unit 1350, and the substrate 1360, then be reflected by the fifth optical unit 1370 and sequentially pass through the substrate 1360 and the fourth optical unit 1350, and then be reflected by the third optical unit 1340 and sequentially pass through the fourth optical unit 1350, the substrate 1360, the fifth optical unit 1370, and the sixth optical unit 1380.

The unit structure of the metasurface of the VR module according to an embodiment may have a cylinder shape or a quadrangular pillar shape.

The phase of the optical signal of the VR module according to an embodiment after passing through the metasurface may vary depending on the diameter of the unit structure.

The metasurface of the VR module according to an embodiment may be made of a polymer, an insulator, or a metallic material.

The metasurface of the VR module according to an embodiment may be an isotropic, anisotropic, birefringent, polarization-dependent, or polarization-independent structure.

FIG. 12 is a conceptual diagram of a VR module according to another embodiment.

Referring to FIG. 12, a VR module 1400 according to an embodiment includes a display unit 1410 that radiates an optical signal and an optical system that includes first to sixth optical units 1420, 1430, 1440, 1460, 1480, and 1490 sequentially disposed on a path of the optical signal, in which the display unit 1410 and the first to sixth optical units 1420, 1430, 1440, 1460, 1480, and 1490 are disposed to be spaced a predetermined interval from each other, the fourth optical unit 1460 includes a first metasurface 1450 that focuses the optical signal and a second metasurface 1470 that faces the first metasurface 1450 and delays a phase of the optical signal by ¼ wavelength, and the fourth optical unit 1460 may allow the optical signal radiated from the display unit 1410 at least three times or more to pass therethrough.

The display unit 1410 may radiate the optical signal. The display unit 1410 may radiate the optical signal to the first optical unit 1420. The display unit 1410 may be disposed in the first direction. The display unit 1410 may be a display panel that radiates the optical signal and may output image information of the VR module. The display unit 1410 may include an LCD, an OLED, an OLEDOS, or a MicroLED.

The first to sixth optical units 1420, 1430, 1440, 1460, 1480, and 1490 may be optical elements that change the phase of the optical signal, such as a collimating lens, a DOE, a phase plate, and a focusing lens. The first to sixth optical units 1420, 1430, 1440, 1460, 1480, and 1490 may be disposed to be spaced a predetermined interval from each other in the second direction perpendicular to the first direction on the path of the optical signal radiated from the display unit 1410, and each of the first to sixth optical units 1420, 1430, 1440, 1460, 1480, and 1490 may be disposed in the same first direction as the display unit 1410. The first to sixth optical units 1420, 1430, 1440, 1460, 1480, and 1490 may be disposed to be spaced a predetermined interval from each other or disposed to be spaced apart from each other at different intervals. A space between the first to sixth optical units 1420, 1430, 1440, 1460, 1480, and 1490 is an empty space, and air may serve as an intermediate medium for the optical signal. The first to sixth optical units 1420, 1430, 1440, 1460, 1480, and 1490 may be collectively referred to as the optical system. Each of the first to sixth optical units 1420, 1430, 1440, 1460, 1480, and 1490 may be an optical element in the form of a thin film or a flat plate. In addition, the first to sixth optical units 1420, 1430, 1440, 1460, 1480, and 1490 are optical elements with a predetermined thickness and are disposed to be spaced a predetermined interval from each other, and thus a certain space is required for accommodation. By including the plurality of optical units corresponding to the first to sixth optical units 1420, 1430, 1440, 1460, 1480, and 1490 in the optical system, there is an effect of reducing a focal distance between the image of the VR module and the user.

The first optical unit 1420 may allow the optical signal radiated from the display unit 1410 to pass therethrough. The first optical unit 1420 may be disposed to be spaced a predetermined interval from the display unit 1410, and the first optical unit 1420 may be disposed parallel to the display unit 1410. The first optical unit 1420 may be disposed between the display unit 1410 and the second optical unit 1430.

The first optical unit 1420 according to an embodiment may be a linear polarizer that transmits a P wave of the optical signal. The first optical unit 1420 may transmit only a P wave polarization of the optical signal radiated from the display unit 1410 and may reflect an S wave polarization.

The second optical unit 1430 may allow the optical signal that has passed through the first optical unit 1420 to pass therethrough. The second optical unit 1430 may be disposed to be spaced a predetermined distance from the first optical unit 1420, and the second optical unit 1430 may be disposed parallel to the first optical unit 1420. The second optical unit 1430 may be disposed between the first optical unit 1420 and the third optical unit 1440.

The second optical unit 1430 according to an embodiment may be a wave plate that delays the phase of the optical signal by ¼ wavelength. The second optical unit 1430 may delay the phase of the optical signal passing through the first optical unit 1420 by ¼ wavelength relative to the phase of the optical signal prior to passing through the first optical unit 1320.

The second optical unit 1430 according to an embodiment may be a metasurface that delays the phase of the optical signal by ¼ wavelength.

The third optical unit 1440 may allow the optical signal that has passed through the second optical unit 1430 to pass therethrough. The third optical unit 1440 may be disposed to be spaced a predetermined distance from the second optical unit 1430, and the third optical unit 1440 may be disposed parallel to the second optical unit 1430. The third optical unit 1440 may be disposed between the second optical unit 1430 and the fourth optical unit 1460.

The third optical unit 1440 according to an embodiment may be a partially reflective mirror that transmits 50% of the optical signal. The third optical unit 1440 may transmit 50% of the optical signal that has passed through the second optical unit 1430 and reflect 50% of the optical signal.

The fourth optical unit 1460 may allow the optical signal that has passed through the third optical unit 1440 to pass therethrough. The fourth optical unit 1460 may be disposed to be spaced a predetermined distance from the third optical unit 1440, and the fourth optical unit 1460 may be disposed parallel to the third optical unit 1440. The fourth optical unit 1460 may be disposed between the third optical unit 1440 and the fifth optical unit 1480.

The fourth optical unit 1460 according to an embodiment includes the first metasurface 1450 that focuses the optical signal and the second metasurface 1470 that faces the first metasurface 1450 and delays the phase of the optical signal by ¼ wavelength, and the fourth optical unit 1460 may allow the optical signal radiated from the display unit 1410 to pass therethrough at least three times or more.

The fourth optical unit 1460 may allow the optical signal radiated from the display unit 1410 to pass therethrough at least three times or more. The fourth optical unit 1460 may allow the optical signal that has passed through the third optical unit 1440 to pass therethrough, may allow the optical signal that has passed through the fourth optical unit 1460 and been reflected by the fifth optical unit 1480 to pass therethrough again, and may allow the optical signal that has been reflected by the third optical unit 1440 to pass therethrough again.

The fourth optical unit 1460 according to an embodiment may include GaAs. Since the fourth optical unit 1460 passes the optical signal radiated from the display unit 1410, there may be high transmittance of the optical signal.

The first metasurface 1450 and the second metasurface 1470 may be metasurfaces that are disposed on one surface of the fourth optical unit 1460. The first metasurface 1450 and the second metasurface 1470 may be formed in a manner of etching the surface of the fourth optical unit 1460. The first metasurface 1450 and the second metasurface 1470 may implement the optical element having the focusing function in the ultra-thin film form in which the plurality of nano-unit structures are arranged. When the optical signal passes through the metasurface, the phase of the optical signal may be delayed to change the path of the optical signal. When the metasurface is used, the total thickness of the plurality of optical elements may be reduced from several mm to 1 μm or less, thereby improving the performance of the optical module.

The first metasurface 1450 may be disposed on a first surface 1460a of the fourth optical unit 1460. The first surface 1460a may be a surface disposed to face the third optical unit 1440 of the fourth optical unit 1460. The first metasurface may be the metasurface formed by etching the first surface 1460a of the fourth optical unit 1460.

The first metasurface 1450 according to an embodiment may focus the optical signal. The first metasurface 1450 may be the metasurface that functions as the focusing lens that focuses the optical signal. When the optical signal that has passed through the third optical unit 1440 passes through the first metasurface 1450, the optical signal may be focused to a certain focal point.

The second metasurface 1470 may be disposed on a second surface 1460b of the fourth optical unit 1460. The second surface 1460b may be a surface disposed to face the fifth optical unit 1480 of the fourth optical unit 1460. The second metasurface 1470 may be the metasurface formed by etching the second surface 1460b of the fourth optical unit 1460.

The second metasurface 1470 according to an embodiment faces the first metasurface 1450 and may delay the phase of the optical signal by ¼ wavelength. The second metasurface 1470 may be the metasurface that functions as a ¼ delay wavelength plate that delays the phase of the optical signal by ¼ wavelength. When the optical signal that has passed through the fourth optical unit 1460 passes through the second metasurface 1470, the wavelength of the optical signal may be delayed by ¼ wavelength. The second metasurface 1470 may be disposed on the second surface 1460b facing the first surface 1460a on which the first metasurface 1450 is disposed.

The fifth optical unit 1480 according to an embodiment may allow the optical signal that has passed through the fourth optical unit 1460 to pass therethrough. The fifth optical unit 1480 may be disposed to be spaced a predetermined distance from the fourth optical unit 1460, and the fifth optical unit 1480 may be disposed parallel to the fourth optical unit 1460.

The fifth optical unit 1480 according to an embodiment may be a linear polarizer that reflects the P wave of the optical signal and transmits the S wave. The fifth optical unit 1480 may transmit only the S wave polarization of the optical signal passing through the fourth optical unit 1460, and reflect the P wave polarization.

The sixth optical unit 1490 according to an embodiment may allow the optical signal that has passed through the fifth optical unit 1480 to pass therethrough. The sixth optical unit 1490 may be disposed to be spaced a predetermined distance from the fifth optical unit 1480, and the sixth optical unit 1490 may be disposed parallel to the fifth optical unit 1480. An observer may confirm the optical signal passing through the sixth optical unit 1480.

The sixth optical unit 1490 according to an embodiment may be a linear polarizer that transmits the S wave of the optical signal. The sixth optical unit 1490 may transmit the S wave polarization of the optical signal passing through the fifth optical unit 1480.

The optical signal according to an embodiment may sequentially pass through the display unit 1410, the first optical unit 1420, the second optical unit 1430, the third optical unit 1440, and the fourth optical unit 1460 and then be reflected by the fifth optical unit 1480, pass through the fourth optical unit 1460 and then be reflected by the third optical unit 1440, and sequentially pass through the fourth optical unit 1460, the fifth optical unit 1480, and the sixth optical unit 1490.

The unit structure of the metasurface according to an embodiment has cylinder shape or a quadrangular pillar shape, the phase of the optical signal after passing through the metasurface varies depending on the diameter of the unit structure, the metasurface is made of a polymer, an insulator, or a metal material, and the metasurface may have an isotropic, anisotropic, birefringent, polarization-dependent, or polarization-independent structure.

The VR module according to an embodiment may include a frame that fixes the display unit and the optical system on the outside, and a band that may fix the VR module to the observer.

The display unit and the optical system are included inside the frame, and the frame may fix the display unit and the optical system on the outside. The frame includes an opening, and the optical signal passing through the optical system through the opening may be incident on the observer's eyes. The frame may be composed of a shape and material that may protect the display unit and the optical system, and the type of the shape and material thereof is not limited.

The band may fix the VR module to the observer. The band is connected to the outside of the frame of the VR module and may be fixed to the observer in a manner that is wrapped around the circumference of the observer's head. The band may be formed so that the opening of the frame is disposed on the observer's eye, and the optical signal passing through the opening may be incident on the observer's eye. The band may adjust the circumference length that wraps around the observer's head, and the material and shape of the band are not limited.

Although the above description has been made based on embodiments, this is only an example and does not limit the present invention. Those skilled in the art to which the present invention pertains may understand that several modifications and applications that are not described in the present specification may be made without departing from the spirit of the present invention. For example, each component described in detail in the embodiment may be modified and implemented. In addition, differences associated with these modifications and applications are to be interpreted as falling within the scope of the present invention as defined by the following claims.

1. A light-emitting device comprising:
a substrate;
a first electrode and a second electrode disposed to be spaced apart from each other on the substrate;
light-emitting units disposed on the first electrode and the second electrode, electrically connected to the first electrode and the second electrode, and each including a first conductivity-type semiconductor layer, a light-emitting layer, and a second conductivity-type semiconductor layer; and
a semiconductor substrate disposed on the light-emitting unit,
wherein the semiconductor substrate includes:
a first surface including a first region in which a metasurface is formed; and
a second surface opposite to the first surface and being in contact with the light-emitting unit,
the metasurface protrudes in a first direction from the second surface toward the first surface, and
a second region of the first surface, which does not include the first region in which the metasurface is formed, is flat.

2. The light-emitting device of claim 1, wherein the light-emitting unit includes a first opening that controls an area of an optical signal emitted in the first direction, and
an area of the first region in which the metasurface is formed is larger than that of the first opening.

3. The light-emitting device of claim 2, wherein the metasurface includes a plurality of unit structures, and
a phase of the optical signal is delayed by the plurality of unit structures.

4. The light-emitting device of claim 3, wherein the plurality of unit structures include a plurality of cylinders or a plurality of quadrangular pillars protruding from the first surface in the first direction.

5. The light-emitting device of claim 3, wherein a design method of the unit structure is an isotropic, anisotropic, birefringent, polarization-dependent, or polarization-independent design.

6. The light-emitting device of claim 1, wherein the light-emitting device is a vertical-cavity surface-emitting laser having a flip chip structure.

7. The light-emitting device of claim 1, wherein the semiconductor substrate includes at least one of gallium arsenide (GaAs) and gallium nitride (GaN).

8. The light-emitting device of claim 1, wherein the metasurface is formed by micro electro mechanical systems (MEMS).

9. The light-emitting device of claim 1, wherein the metasurface performs at least one of focusing, diverging, and diffracting of an optical signal emitted from the light-emitting unit.

10. (canceled)

11. The light-emitting device of claim 1, wherein the metasurface is formed to be depressed in a second direction from the first surface toward the second surface.

12. The light-emitting device of claim 1, wherein the first electrode and the second electrode are in direct contact with the substrate.

13. The light-emitting device of claim 11, wherein the first electrode and the second electrode are disposed in the second direction from the light emitting unit.

14. The light-emitting device of claim 1, wherein an optical signal emitted from the light emitting unit is emitted to the outside through the first region.

15. The light-emitting device of claim 1, wherein the second region is disposed in a form that surrounds the first region.

16. The light-emitting device of claim 15, wherein an area of the second region is smaller than an area of the first region.

17. The light-emitting device of claim 1, wherein the first electrode and the second electrode are disposed between the light emitting unit and the substrate.

18. The light-emitting device of claim 2, wherein the first opening is disposed between the first region and the first electrode.

19. A virtual reality (VR) module comprising:
a display unit that radiates an optical signal;
an optical system including a first optical unit, a second optical unit, a third optical unit, a fourth optical unit, a fifth optical unit, and a sixth optical unit sequentially disposed on a path of the optical signal; and
a substrate disposed between the fourth optical unit and the fifth optical unit,
wherein the display unit and the first to sixth optical units are disposed to be spaced a predetermined interval from each other,
the fourth optical unit focuses the optical signal,
the fifth optical unit delays a phase of the optical signal, and
at least one of the fourth optical unit and the fifth optical unit is a metasurface disposed on one surface of the substrate.

20. The VR module of claim 19, wherein the first optical unit is a linear polarizer that transmits a P wave of the optical signal, the second optical unit is a wave plate that delays the phase of the optical signal by ¼ wavelength, the third optical unit is a partially reflective mirror that transmits 50% of the optical signal, the fifth optical unit delays the phase of the optical signal by half a wavelength, and the sixth optical unit is a linear polarizer that transmits an S wave of the optical signal.

21. The VR module of claim 19, wherein the fourth optical unit is a metasurface that is disposed on a surface of the substrate facing the third optical unit, and the fifth optical unit is a metasurface that is disposed on the surface of the substrate facing the sixth optical unit.
